(19) United States
(12) Patent Application Publication
(10) Pub. No.: US 2017/0225271 A1
(43) Pub. Date: Aug. 10, 2017

(54) SUBSTRATE MANUFACTURE

(71) Applicant: BAE SYSTEMS plc, London (GB)

(72) Inventors: DARREN JAMES GOODMAN, Portsmouth, Hampshire (GB); ALLAN CHARLES GRIMALDI, Portsmouth, Hampshire (GB)

(73) Assignee: BAE SYSTEMS plc, London (GB)

(21) Appl. No.: 15/500,824

(22) PCT Filed: Aug. 6, 2015
(86) PCT No.: PCT/GB2015/000232

§ 371 Date: Jan. 31, 2017

(30) Foreign Application Priority Data
Aug. 6, 2014 (GB) 1413925.7

(51) Int. Cl. B23K 26/388; H05K 3/00; B23K 26/402

(52) U.S. Cl. CPC B23K 26/388; B23K 26/402; H05K 3/0029; H05K 3/0032; H05K 2203/081; B23K 2201/36

(57) ABSTRACT

The invention relates to a method of forming a void with a circular cross section in a substrate, more particularly to forming through holes electronic substrates The method comprising the steps of causing a laser cutter to traverse in an arc to an intended circumference of the void, traversing the intended circumference of the void at least once, wherein the lead in from the arc to the circumference comprises a radius.

The invention relates to a method of forming a void with a circular cross section in a substrate, more particularly to forming through holes in electronic substrates.

The manufacture of substrates for use in electronic systems where a heat sink is required follows a standardised process which begins with a single piece of substrate. The process involves the substrate having a number of voids created on a specified portion of the substrate. These voids can number from single figures to hundreds but all voids take time to create, which is an important factor within the manufacturing industry. The voids are then filled with a conductive material, preferably copper, by a process such as sputtering or electroplating. This process leaves excess conductive material on the tops and bottoms of the said filled voids which must then be removed to ensure the tops and bottoms of the said voids are flush with the substrate. During removal an inadequately filled void can lead to chipping along the void edge, between the substrate and the conductive material. This can lead to a less durable substrate.

Within the prior art, the creation of a void in a material substrate may be achieved using a variety of methods, including techniques wherein the cutting device is positioned vertically above the substrate and remains in a static attitude while the void is created, the cutting device being the diameter of the intended void. Upon completion the cutting device is stopped until the cutting device is positioned above the location for the next desired void, this is typically done by movement of the laser cutter or the substrate.

Alternatively the laser cutter's beam may be narrower than the intended circumference of the void and is used to cut a void in the substrate by locating the laser above the intended edge of the desired void and having the laser, whilst cutting, travel in a circular motion until it reaches its original point of cutting, whereby the void is created and the laser can be stopped until it is positioned above the edge of the next void to be created.

Alternatively, the laser cutter may be substituted by another cutting tool including a mechanical drill or a punch. The drill is located over the area where the void is to be created. The drill is started and is pushed into the substrate to create the void. The drill is then withdrawn and either the drill or the substrate is adjusted to position the drill over the next void that is to be formed.

According to a first aspect of the invention there is provided a method of forming a void with a circular cross section in a substrate, said method comprising the steps of causing a laser cutter to traverse in an arc to an intended circumference of the void, traversing the intended circumference of the void at least once, wherein the lead in from the arc to the circumference comprises a radius.

In a preferred arrangement, the laser cutter's beam has a diameter less than that of the desired intended circumference of the circular void, to allow the required cutting sequence

The laser cutter may be a directed energy laser cutter, preferably a carbon dioxide laser with an assist gas. The assist gas may be selected from air, oxygen, nitrogen or argon assisted gas. In a preferred arrangement it is a carbon dioxide laser, used to vaporise the substrate and a directed, pressurised oxygen stream to act as the assist gas.

In electronic component manufacture the substrate used may typically be a material which has a high thermal conductivity. In a preferred arrangement the substrate is selected from a ceramic, a polymer or a composite. In a preferred arrangement the ceramic may be aluminium nitride, although alumina and beryllium oxide and PCB substrates may commonly be used.

Void creation in such substrates is often difficult to control, due to the high thermal conductivity of substrates such as, for example, aluminium nitride. Aluminium nitride is difficult to process, because when subjected to heat energy from a laser cutter, this energy may be absorbed without melting or vaporising the aluminium nitride substrate.

The voids in complex electronic component board are required to be extremely accurate in respect of their shape, in terms of the edges of the circumference of the void and the internal wall, the diameter of the wall of the void through the substrate, and the smoothness of the surface of the void wall.

Once the void has been created it is inspected to check for issues that may have arisen during the void creation process that may affect the deposition of the conductive material to the walls of the void, these defects may include misshapen or chipped voids or a lack of smoothness, whether due to chips or the presence of contaminates as a result of the void creation.

The void in a substrate may be a through hole, or a blind hole. A through hole may be required to be filled with a conductive material to allow an electric current or heat transfer to pass from one side of the substrate to the other. This is commonly done in the industry by a process of sputtering, which is a process where thin films of the conductive material, preferably in this case a conductive material such as copper, are built up by being deposited onto a surface.

After the walls of the void are covered in a thin film of the conductive material the thickness may be increased by an electroplating technique whereby an electric current attracts further particles of the said conductive material to build up the thickness until the void is substantially filled with conductive material. A poorly filled void may have a detrimental impact in the reliability and longevity of the substrate as it may cause poor thermal transfer and place the substrate under increased thermal strain.

Throughout the process of substrate construction there are a number of issues which may affect the ability to fill the void with conductive material effectively. These primarily relate to the smoothness of the wall of the void as this affects the ability to effectively coat the surface of the wall with conductive material during sputtering. Void walls containing contaminants, debris or which are pitted can lead to areas which are un-sputtered, i.e. where conductive material has failed to adhere, and as a result, the fill becomes uneven, potentially leaving gaps between the void wall and the conductive material.

One of the risks of the re-solidified substrate, post lasering, is that it can become loose during its life time and this may lead to detachment of the plated metallisation.

Once sputtering and electroplating has been completed the said void is filled and the substrate enters the process of removing excess conductive material. In this stage the excess conductive material is ground down to make it flush with the substrate, however this can cause problems as a misshapen edge or a lack of adhesion between the conductive material and the void can cause chipping, which reduces the integrity of the filled void, the substrate, and as a result the overall electronic component.

A further issue with void creation in a substrate is the ability to achieve a full and complete and filled void. While filling said void, gaps near the void wall created by an undulating or pitted void wall, or a misshapen void may lead to the formation of a large cavity at the centre of the conductive material. A large cavity can lead to poor longevity of the substrate, as detailed previously.

In a preferred arrangement the laser cutter starts the cutting process from the substantial centre of the intended circumference of the void and in yet more preferably the laser cutter finishes the cutting process in the substantial centre of the thus formed void. By starting the cutting process in the substantial centre of the void or by finishing the cutting process in the substantial centre of the void it lessen the likelihood of a misshapen edge.

In a highly preferred arrangement the laser cutter creates the void by traversing the intended circumference of the void at least once, in a range from 1 to 4 times, more preferably at least twice.

In a preferred embodiment the substrate is an aluminium nitride sheet where at least one void is created by the use of a laser cutter, comprising a carbon dioxide laser and oxygen assist gas. Preferably the laser cutter is moved to the centre of the intended void; the laser cutter is then turned on and allowed to fully penetrate the substrate. Once fully penetrated the laser cutter is moved in an arcing motion to the outermost of the intended circumference of the void. The laser cutter continues on a circular path around the circumference of the void until it reaches the point of the circumference at which it started the traversal of the circumference. The laser cutter preferably makes a repeat pass of the circumference following the exact circumference route it had taken on the original traversal in order to clean debris away from the void wall. Following the second circumference traversal the laser cutter will preferably return to the centre, in an arcing motion, to end up at the original point prior to the laser cutters movement. The laser cutter will then be turned off and either the laser cutter or substrate will move until the laser cutter is at the location of the centre of the next void to be created.

In a preferred arrangement the circular void has an angled inner wall slope, having an angle in the range from between 0 and 20 degrees, with respect to the axis which is perpendicular to an upper surface of the substrate. In a highly preferred arrangement the circular void is a frustroconical shape.

The use of aluminium nitride over a more traditional component for substrates, such as alumina is preferred as it has higher thermal conductivity and is less toxic. Further to this, the specific use of oxygen as an assist gas to the carbon dioxide laser reduces the formation of elemental aluminium around the void circumference. A further advantage of starting the cutting process in the centre of the intended void and making preferably a maximum of two traversals of the circumference of the intended void, is that many of the imperfections relating to the smoothness of the void walls are avoided as the second traversal of the circumference aids in cleaning any possible cutting debris which may amount on the walls of the void and so will improve the effectiveness of the sputtering process and the ability for the conductive material to adhere to the void wall in its entirety. In a highly preferred arrangement the circular void inner wall is a frustroconical shape, which may also improve the effectiveness of the sputter process by increasing the surface area of the void wall, providing a larger area for the conductive material to adhere to.

Whilst the method has been described above, it extends to any inventive combination of the features set out above, or in the following description, drawings or claims.

Exemplary embodiments of the device in accordance with the invention will now be described with reference to the accompanying drawings in which:

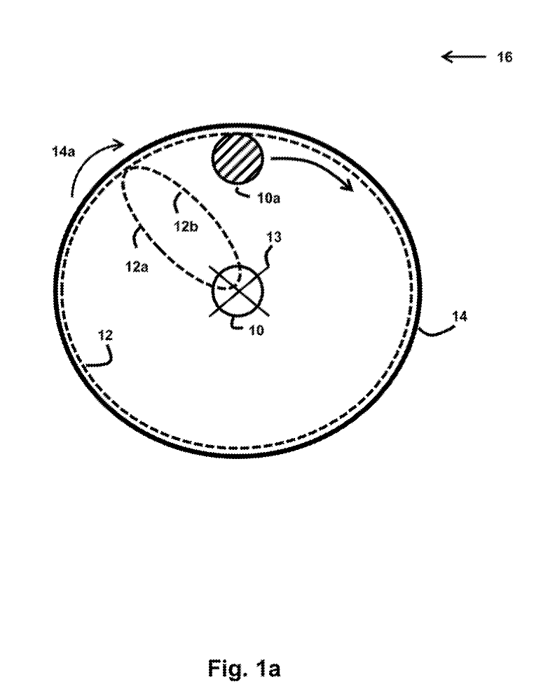

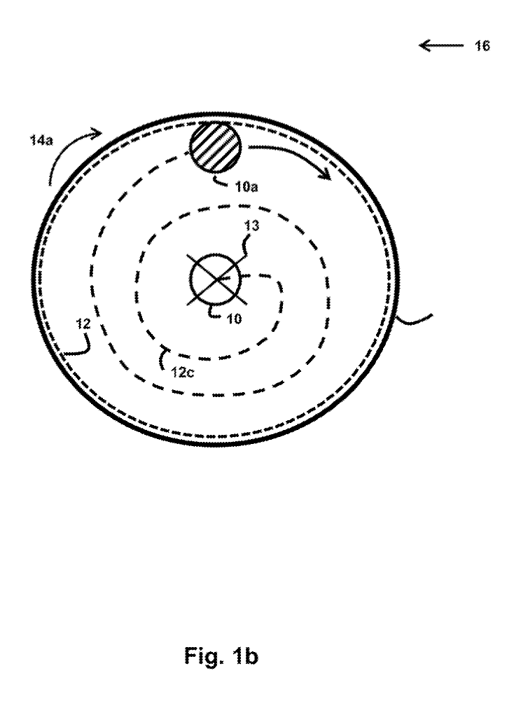

FIG. 1a: Is a schematic of the path taken by the laser cutter during void creation.

FIG. 1b: Is an alternative schematic of the path taken by the laser cutter during void creation.

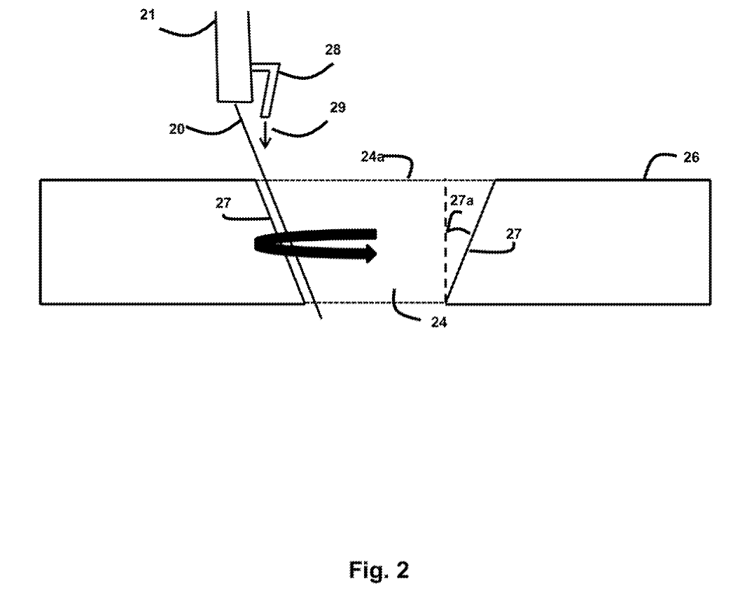

FIG. 2: Is a cross-section of the void creation showing void walls and possible shape.

Referring to FIG. 1a there is shown a top view of a section of a substrate 16 with a laser cutter 10 focused at the centre of the intended circumference 14a. The void 14 is created by moving the laser cutter 10 from the centre 13 of the substrate 16 in an arc 12a to the intended circumference 14a of the intended void 14. The moving laser cutter 10a travels in a circular fashion around the intended circumference 14a of the void 14, on a cutting path 12. The moving laser cutter 10a travels on the cutting path 12 for a second pass before returning in an arc 12b to the centre of the created void 14.

Referring to FIG. 1b there is shown a top view of a section of substrate 16 with a laser cutter 10 focused at the centre of the intended circumference 14a. The void 14 is created by moving the laser cutter 10 from the centre 13 of the void 14 in a spiral cutting path 12c to the intended circumference 14a of the intended void 14. The moving laser cutter 10a travels in a circular fashion around the intended circumference 14a of the intended void 14, on a cutting path 12. The moving laser cutter 10a travels on the cutting path 12 for a second pass before returning in an arc 12b to the centre of the intended void 14.

Referring to FIG. 2 there is shown a cross section of substrate 26 with a laser cutter 20 originally from a laser 21 and an assist gas tube 28 providing a flow of an assist gas 29 following a path of the intended circumference 24a of the intended void 24. The laser cutter 21 is perpendicular to the substrate 26 but focused to create the intended void 24 with a sloping void wall 27 within an acceptable tolerance 27a.

1. A method of forming a void with a circular cross section in a substrate, said method comprising:
causing a laser cutter to traverse in an arc to an intended circumference of the void; and
traversing the intended circumference of the void at least once;
wherein the lead in from the arc to the circumference comprises a radius.

2. A method according to claim 1, wherein the laser cutter is traversed in a spiral pattern towards the circumference of the void.

3. A method according to claim 1, wherein said substrate is selected from a ceramic, polymer or composite material.

4. A method according to claim 3, wherein the ceramic is aluminium nitride.

5. A method according to claim 1, wherein said laser cutter is a carbon dioxide laser with an assist gas.

6. A method according to claim 1, wherein said laser cutter starts from the centre of the intended circumference of the void.

7. A method according to claim 1, wherein said laser cutter ends at the centre of the intended circumference of the void.

8. A method according to claim 1, wherein the intended circumference of the void is traversed in the range of from 1 to 4 times.

9. A method according to claim 1, wherein the void has an inner wall slope of between 0 and 20 degrees.

10. A method according to claim 9, wherein the void has a frustroconical shape.

11. A method according to claim 1, wherein the intended circumference of the void is traversed in the range of from 2 to 4 times.

12. A method according to claim 1, wherein the intended circumference of the void is traversed in 2 times.

13. A method according to claim 1, wherein said laser cutter starts from the centre of the intended circumference of the void, the method further comprising:
at the end of a second or subsequent traversal of the intended circumference, causing the laser cutter to traverse in a second arc back to the centre;
wherein the arc and the second arc have common start and end points, and the radius connects those endpoints.

14. A method according to claim 13, wherein the arc and the second arc form an ellipse shape, and the radius is the major axis of the ellipse shape:

15. A method according to claim 1, wherein said laser cutter starts from the centre of the intended circumference of the void, the method further comprising:
at the end of a final traversal of the intended circumference, causing the laser cutter to traverse in a second arc back to the centre;
wherein the arc and the second arc have common start and end points thereby forming a shape having the radius as its major axis.

16. A method according to claim 1, wherein the laser cutter starts from the centre of the intended circumference of the void and is traversed in a spiral pattern towards the circumference of the void, the spiral including the arc, the method further comprising:
at the end of the second traversal of the intended circumference, causing the laser cutter to traverse in a second arc back to the centre;
wherein the spiral and the second arc have common start and end points.

17. A method according to claim 1, wherein the laser cutter starts from the centre of the intended circumference of the void and is traversed in a spiral pattern towards the circumference of the void, the spiral including the arc, the method further comprising:
at the end of the second or subsequent traversal of the intended circumference, causing the laser cutter to traverse in a second arc back to the centre;
wherein the spiral and the second arc have common start and end points.

18. A method according to claim 1, wherein said laser cutter starts from the centre of the intended circumference of the void, the method further comprising:
at the end of a final traversal of the intended circumference, causing the laser cutter to traverse in a second arc back to the centre;
wherein the spiral and the second arc have common start and end points.

19. A method of forming a void with a circular cross section in a substrate, said method comprising:
causing a laser cutter to traverse in a first arc from the center of the void arc to an intended circumference of the void;
traversing the intended circumference of the void 2 or more times with the laser cutter; and
at the end of a final traversal of the intended circumference, causing the laser cutter to traverse in a second arc back to the centre;
wherein the first arc and the second arc have common start and end points.

20. The method of claim 19, wherein the circular void inner wall is a frustroconical shape, having an angle in the range from up to 20 degrees, with respect to the axis which is perpendicular to an upper surface of the substrate.
